(19) United States
(12) Patent Application Publication
(10) Pub. No.: US 2004/0030982 A1
(43) Pub. Date: Feb. 12, 2004

(54) Information exchange system

(76) Inventors: Jane Aldridge, Cambridge (GB); Philip Michael Gaffney, Cambridge (GB)

Correspondence Address: BEYER WEAVER & THOMAS LLP, P.O. BOX 778, BERKELEY, CA, 94704-0778, US

(21) Appl. No.: 10/381,332

(22) PCT Filed: Sep. 21, 2001
(86) PCT No.: PCT/GB01/04239

(30) Foreign Application Priority Data
Sep. 23, 2000 (GB) 0023401.3
Dec. 27, 2000 (GB) 0031613.3

(51) Int. Cl. H03M 13/00

(52) U.S. Cl. 714/776

(57) ABSTRACT

A method and apparatus is provided for the automatic transfer of data across a communications network. The data is divided into batches prior to transfer and a record of the batches is maintained, so that in the event of a communications failure or a disconnection the transmission of data can be resumed from the point where it left off. By maintaining a record of the batches it is not necessary to re-transmit the entire file when the transfer is disrupted. There is also provided a system for transmitting large attachments (102) to emails (101) wherein the attachment (102) is sent to an intermediate server (108) and a token (109) is generated which is sent both to the intermediate server (108) and to the end receiver (107), which allows the attachment (102) to be downloaded from the intermediate server (108) to the end receiver (107) at a later time.

### FIELD OF THE INVENTION

The present invention relates to a system of transferring data and in particular large amounts of data, over a communications network such as the Internet.

### BACKGROUND TO THE INVENTION

It is a function of a data terminal to exchange data with another linked terminal or terminals, whether this is by a direct local interconnection or remote connection over a communications link or other remote connection over a networking system such as the Internet. In what has been called “The information age” the efficient and economical transfer of data has become necessary, particularly over communications networks.

When a data terminal is intended for use as an Internet terminal it will typically connect to a server located at an Internet Service Provider (ISP) which is able to provide onward connection to the Internet. In addition to this, the ISP will typically provide other services such as access to news groups and electronic mail (E-mail) services. However, even though an ISP may typically provide such onward connection there may be situations where onward connection is restricted or even deliberately isolated. For example where the ISP connection is provided as a closed facility within a business functioning as an extension of the company Intranet.

Connection to an ISP from an Internet terminal can be achieved in two main ways:

Firstly, a continuous connection can be provided between the ISP and the Internet terminal.

Secondly, the Internet terminal can be provided with a temporary connection to the ISP, which is initiated from the Internet terminal, but which could also be initiated from the ISP. An example of this type of connection would be a standard dial-up link over a land or mobile telephone network or a digital link such as an Integrated Services Digital Network (ISDN). In order to operate this temporary connection, computer programmes exist that contain the functionality to dial the appropriate telephone number and establish a data connection with equivalent equipment at the ISP. It is common for these programmes to include the facility for the user to select a time interval to establish such a connection repeatedly and automatically. Further programmes exist that can utilise this data connection to exchange information between the Internet terminal and the ISP using the accepted and agreed data protocols.

In the first case, information can be passed in either direction at any time that a request is made to the server by the end station. Thus, it would be normal for the end station to request service at very regular intervals and for all available data transfers to be attempted at the earliest opportunity and to continue until all data transfers are completed.

In the second case, information can only be passed in either direction when a connection is established and a request made for service by the end station. Thus, it would be normal for the end station to dial-in at intervals and for all available data transfers to be attempted at the earliest opportunity and to continue until all data transfers are completed.

It follows from both cases above that it is often ideal for service to be requested as frequently as possible, but the desirability of this may be significantly affected by the various costs associated with the means of connection. On the one hand, a free connection may mitigate in favour of frequent requests for service and on the other hand a high fixed connection charge may mitigate in favour of infrequent requests for service.

As the size of typical content being delivered to or from the end station increases it is becoming increasingly common for long established or intermittent poor line conditions to result in failed transfers and a need for repeated connection to send such large files again. The repeated information may again be further subject to such failures and some service providers may terminate connection after a maximum permitted time making some file transfers almost impossible.

Furthermore, communications networks are becoming increasingly busy, and are particularly busy at certain times of day. As a result network providers often set different tariffs for different times of day.

It is frequently the case that service providers involved in the transmission of e-mail messages over a network limit the size of the message that may be passed. Although the originator's ISP may not impose any limit on the sending of mail, there may be a restriction at the receiving ISP on the size of individual messages or on the total size of the mailbox or both. It is unlikely that either the receiver or the originator will be aware of this limitation before a particular message is sent.

### SUMMARY OF THE INVENTION

According to a first aspect of the present invention a method of transferring data via a communications network from a first network node to a second network node, comprises the steps of:

dividing the data into batches;

transferring information to the second node from the first node in the batches, and maintaining a record of each batch; and

in the event of a transmission failure or disconnection, reestablishing a connection between the first node and the second node and transferring to the second node from the first node only that batch or those batches of the data not yet successfully received by the second node.

Preferably, the record includes information about the size and location of each batch within the data.

Preferably, the method further comprises the step of scheduling the connection and disconnection of the first node or second node to the communications network. In this case a data transfer can be interrupted by a scheduled or unscheduled disconnection of one of the nodes from the network and the data transfer restarted at a later time from the point at which it was interrupted, without having to start the transfer from the beginning.

Preferably, the method further comprises the step of reassembling the batches of information at the second node in accordance with the record.

Preferably, the communications network comprises the Internet.

The method may also include the step of wrapping each batch of data in an alternative protocol.

The method may further comprise the steps of:

compressing the information at the first node; and

decompressing the information received from the first node at the second node.

The method may also further comprise the steps of:

encrypting the information sent to the second node; and

decrypting the information received from the first node as permitted and required at the second node.

Preferably, the first and second nodes comprise a network server and an end station. The scheduling of the connection and disconnection of the end station to the communications network is preferably dependent upon various parameters derived locally, including information down loaded from the server to the end station.

Preferably, the data includes at least one of e-mails, attachments to e-mails and web pages.

An apparatus for transferring data via a communications network from a first network node to second network node, according to the first aspect of the present invention, comprises:

means to divide the data into batches;

means to transfer information to the second node from the first node in the batches, and maintain a record of each batch;

means to reestablish a connection between the first node and the second node in the event of a transmission failure or disconnection; and

means to transfer to the second node from the first node only that batch or those batches of the data not yet successfully received by the second node.

Preferably, the apparatus includes means to schedule the connection and disconnection of the first node or second node to the communications network.

Preferably the apparatus further includes means to reassemble the batches of information at the second node in accordance with the record.

Preferably, the communications network comprises the Internet.

The apparatus may include means to wrap each batch of data in an alternative protocol.

The apparatus may further be adapted to:

compress the information at the first node; and

decompress the information received from the first node at the second node.

The apparatus may also be adapted to:

encrypt the information sent to the second node; and

decrypt the information received from the first node as permitted and required at the second node.

Preferably, the first and second nodes comprise a network server and an end station.

Preferably, the scheduling of the connection and disconnection of the end station to the communications network is dependent upon various parameters derived locally, including information down loaded from the server to the end station.

The data preferably includes at least one of e-mails, attachments to e-mails and web pages.

According to a second aspect of the present invention a method of transferring an email and an attachment from a first end station to a second end station, comprises the steps of:

generating a token containing information about the attachment;

sending the email and a copy of the token to the second end station;

sending the attachment and a copy of the token to an attachment server in accordance with the method of the first aspect; and

sending the attachment and a copy of the token to the second end station from the attachment server in accordance with the method of the first aspect.

Preferably, the token contains information gathered from one or more of the first end station, the second end station, an intermediate server and the attachment. Preferably, the attachment server generates reports relating to the status of the uploading or downloading of the attachment to or from the attachment server.

According to the second aspect of the present invention, an apparatus for transferring an email and an attachment from a first end station to a second end station, comprises:

means for generating a token containing information about the attachment;

means for sending the email and a copy of the token to the second end station;

means for sending the attachment and a copy of the token to an attachment server in accordance with the apparatus of the first aspect; and

means for sending the attachment and a copy of the token to the second end station from the attachment server in accordance with the apparatus of the first aspect.

Preferably, the token contains information gathered from one or more of the first end station, the second end station, an intermediate server and the attachment. Preferably, the attachment server includes means to generate reports relating to the status of the uploading or downloading of the attachment to or from the attachment server.

### BRIEF DESCRIPTION OF THE DRAWINGS

Examples of the present invention will now be described with reference to the accompanying drawings, in which:

FIG. 1 is a block diagram illustrating the functionality of a network server operating in accordance with the present invention;

FIG. 2 is a block diagram illustrating the functionality of an end station operating in accordance with the present invention;

FIG. 3 is a schematic representation of a system for sending e-mail and attachments in a conventional manner; and,

FIG. 4 is a schematic representation of a system for sending e-mail and attachments in accordance with one embodiment of the present invention.

### DETAILED DESCRIPTION

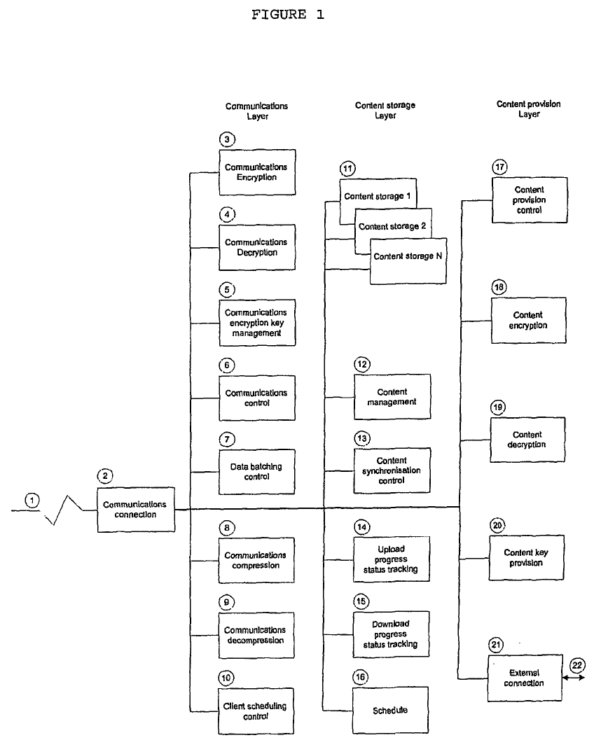

FIG. 1 is a block diagram of apparatus to provide the functions of an Internet Service Provider (ISP) server operating in accordance with the current invention. The block diagram illustrates functionality that may be embodied within the ISP server as software or alternatively provided or attached as hardware or a combination of the two.

The server provides the ISP with the ability to provide content to an end station and receive content from an end station. The server functionality includes features required for the control and management of the end station operation.

The content being exchanged with the ISP server may be of various types and formats including for example documents, e-mail, web pages, images, audio, video, games software and files of various other function and format.

The ISP server is represented as a single machine but may consist of a number of machines providing similar functionality overall or be an integral part of another machine or system that also performs other functions. The ISP server has similar functionality to a standard ISP server with the addition of other specific functions to enable it to operate in accordance with the present invention.

The ISP server has standard communications connection channel 2 linking to communications channel 1. The communications channel 1 is the medium that connects the end station to the server. Examples include a communications channel over a telephone line using modems, a digital Integrated Services Digital Network (ISDN) connection, a high-speed Digital Subscriber Line (DSL) link or a cable modem connection, a digital connection over a mobile network or a combination of several similar connections. The communications connection 2 is the logical connection means between either the end station or server and the communications channel. The most appropriate logical connection will depend on the particular installation. For example a dedicated dial-up network adapter and modem may be required, or a link to an existing TCP/IP protocol network may be appropriate.

The ISP server provides client scheduling control 10 to instruct the end station when to schedule future connections and this information is transferred as schedule 16. This will take into account both the users' preferences and the server requirements before instructing the end station on a specific schedule. This feature allows the ISP to perform load balancing and the user to have a clear idea of when the system will be updated. By these means, the server will cause the end station to connect to the server or to answer calls from the server at various predefined times and intervals in order to facilitate the optimum transfer of content. It is also possible to cause the end station to connect to other servers and services autonomously, to transfer pre-arranged content directly or to have an alternative or default connection available in case of problems with the preferred connection.

Content management 12 provides for review and control over the data for synchronisation. Content stored and designated for synchronisation is periodically reviewed against various criteria and parameters and the content requiring synchronisation is submitted to the content synchronisation control. This synchronisation may be accomplished in various ways as the copy at either the end station or server may be designated to be overwritten or both may be reviewed against more complex criteria in order to propagate the required version. Content external to the ISP server or service may also be included for review.

The various content storage areas 11 allow the storage of different and varying types of content on the server on behalf of the user. The content placed in these areas is synchronised with similar areas at the end station. The server provides the content synchronisation control 13 to manage this activity. This process will take due note of the user preferences and server or content provider requirements to prioritise the exchanges necessary to achieve the synchronisation. Content external to the ISP server or service may also be included for synchronisation.

The ISP server provides data batching control 7 so that large exchanges of data are broken down into smaller batches and transmission records are maintained at the server by upload progress status tracking 14 and by download progress status tracking 15. In this way the transmission of content may be partitioned at any point and the activity resumed at a later time. These records are maintained in non-volatile storage so that data exchange can be resumed without loss. In this way data exchanges can be continued following deliberate suspension, deliberate termination or unintentional disruption, interruption or termination of the line and other disruption such as a power failure. In addition any missing batches of data can be re-sent allowing for recovery after intermittent errors.

In one example, each programme to be transmitted is allocated a programme number, and each programme consists of a number of files. Each file consists of one or more batches. The batches can be of variable length but in this example are of fixed length, each batch containing 16384 bytes, a convenient size for web pages. Each file starts at byte 0 and the batches are identified by byte count, i.e. batch 1 is byte 0 to byte 16383, batch 2 is byte 16384 to 32767 etc. A number of control files are also maintained which contain information about the amount and order of the data contained in each corresponding programme file. Each control file may include for example a programme identifier, a programme title, a programme data and time, file identifiers, file titles, file location in a directory structure, file checksum, temporary file number, temporary file starting point and temporary file length. Control files may also contain subscription information and progress information, such as a percentage delivered.

The data is transferred in batches and control files are transferred at the same time. The receiver can check if all the batches have successfully received by tallying the received data with the control files. A request for individual batches not received can then be made. For example the demand for a batch of data could take the form of a request for a web-page where the Universal Resource Locator (URL) is as follows:

AA_BBBBB_CCCCC_DDDDDDDDD_EEEEEEEEE.htm

where:

AA indicates the type of message

BBBBB indicates the program number

CCCCC indicates the file number

DDDDDDDDD indicates the starting point in the file

EEEEEEEEE indicates the batch size

In this example it can be seen that each individual batch of data may be downloaded from any server at any location that has been provided with the identical data. It may also be seen that, provided the starting point and batch size are consistent, these batches of data may be provided in a rearranged order and would require a key to be provided from the server in order to properly arrange them again.

The ability to re-send individual batches of data to complete missing portions of a content file and scheduling to guarantee connection at predetermined times allows the server to distribute large content on a broadcast or streaming basis to a large number of recipients. In the normal course of events communication errors encountered during the transmission would result in errors in the content file that cannot be corrected during the transmission, as the broadcast technique does not allow for individual errors to be easily corrected. The ability to identify individual batches of data allows these errors to be corrected at a later time by re-sending missing data to an individual end station or for the end station to substitute the replacement data by monitoring a subsequent identical broadcast transmission. This permits the ISP to distribute large content files with a significant saving over individual point-to-point distribution.

The server provides facilities for communications encryption 3 before transmission to the end station and communications decryption 4 following receipt. These facilities match those provided at the end station and operate in conjunction with them. This encryption provides additional security over the communications channel between the server and the end station. The keys necessary to encrypt and decrypt the communications are provided to the server by communications encryption key management 5, which operates in collaboration with similar services at the end station. Any agreed encryption protocol may be used.

The server provides facilities for communications compression 8 before transmission to the end station and communications decompression 9 following receipt. These facilities match those provided at the end station and operate in conjunction with them. This compression may provide greater efficiency in that the time taken to transfer an amount of data may be reduced and this may be applied to any type of content, for example HTML, XML, SGML, WML or even previously compressed formats such as JPEG or MPEG or others.

The communications control 6 provides the co-ordination of the communications process including the management of the connection process, data batching, data compression and data encryption.

The server manages the external control of data exchange with content provision control 17. Content to be onward transmitted externally or obtained externally on behalf of the user can be interchanged via the external connection 21 and suitable data communication channel 22. An example of such a communications channel is the Internet. Content provision control may also act to provide and coordinate content synchronisation to external data sources. Thus the system may provide controlled and regulated synchronisation between many servers and end stations acting in order to propagate information as required. For example, the system may act to provide common services to many organisations physically located over a number of sites.

Data content may be further secured under such control using content encryption 18 and content decryption 19. The keys to enable such encryption and decryption may be provided by the content key provision 20, which provides this service to both the server and end station. This additional security allows both user and content provider to protect the content so that it may only be accessed as authorised. Examples of such uses would include allowing the user to protect confidential e-mail and documents so that they could only be read by the intended recipient and allowing content providers to download content and allow access only under the terms of licensing conditions. An additional level of security could be included by only allowing encrypted documents to be passed between subscribers connecting directly to the ISP thus providing an effective electronic equivalent to the postal courier service.

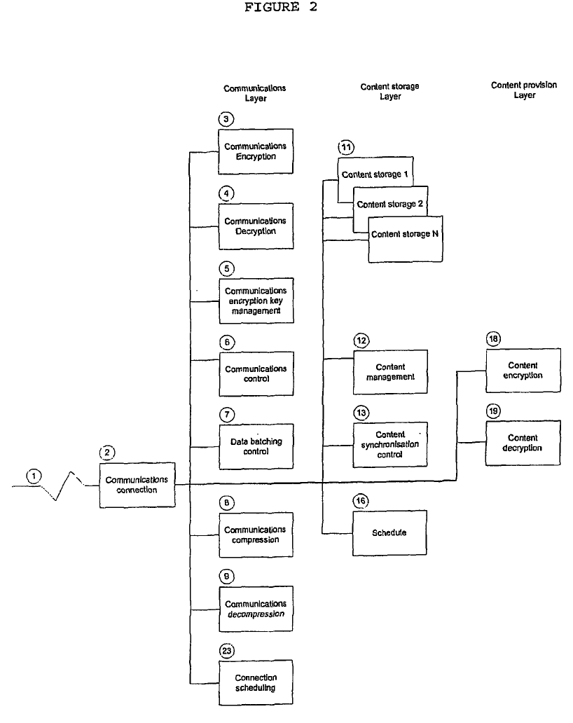

FIG. 2 is a block diagram of apparatus operating in accordance with the present invention to provide the functions of an end station. The block diagram illustrates functionality that may be embodied within the user's machine as software or alternatively provided or attached as hardware or a combination of the two.

The end station provides the user with the ability to access content provided by an ISP server and provide content back to the ISP server where that ISP server is provided with the appropriate compatible means according to the present invention.

The end station may be used on-line where an active connection to the ISP exists or off-line where no active connection to the ISP exists provided that a connection can be established from time to time.

The present example describes an end station that provides the means to exchange such content in a controlled and organised way such that the available communications and server resources are utilised in a most efficient manner. The use of such an end station has numerous benefits for the user, the ISP and the content provider, which will be described later.

The end station is represented as a single entity but may consist of a number of machines providing similar functionality or be an integral part of another machine or system that also performs other functions. Examples of various embodiments of such an end station might include a program running on a computer terminal or embedded within another device such as a mobile telephone handset.

The end station has standard communications connections 2 linking to communications channels 1, as described with reference to FIG. 1.

The end station may be connected to the ISP by various means. It may be continuously linked to the ISP by an appropriate connection, for example a Digital Subscriber Line (DSL) connection or other network interface. The end station may link to the ISP server by use of a dial up connection, either initiating or receiving the call. The connection scheduling 23 allows the server to control connection settings and schedules in order to manage this process and for the user to signal preferences and priorities back to the server. The scheduling parameters are retained in a schedule 16. Examples of the parameters that may be controlled are dial out times, method of connection, upload and download preferences and priorities, requests for content and acceptable times for incoming calls to be answered. Information may be retained not only to control connection to the main server that determines the schedule but also to control alternative or additional connections to other services where this is appropriate.

The end station also provides data batching control 7 in a similar manner to the server, and transmission records are temporarily maintained for each batch at the server. The transmission records may be alternatively be maintained at the end station.

The end station provides facilities for communications encryption 3 before transmission to the end station and communications decryption 4 following receipt. These facilities match those provided at the server and operate in conjunction with them. Communications encryption key management 5 provides the keys necessary to encrypt and decrypt the communications, which operates in collaboration with similar services at the server.

The end station provides facilities for communications compression 8 before transmission to the server and communications decompression 9 following receipt. These facilities match those provided at the server and operate in conjunction with them.

The communications control 6 provides the co-ordination of the communications process including the management of the connection process, data batching, data compression and data encryption.

The various content storage areas 11 allow the storage of different and varying types of content by the user. The content placed in these areas is synchronised with similar areas at the server. Content synchronisation control 13 is provided to manage this activity in collaboration with similar facilities located at the server. This process will take due note of the user preferences and server or content provider requirements to prioritise the exchanges necessary to achieve the synchronisation.

Content management 12 provides for review and control over the data for synchronisation. Content stored and designated for synchronisation is periodically reviewed against various criteria and parameters and that content requiring synchronisation is submitted to the content synchronisation control. This synchronisation may be accomplished in various ways as the copy at either the end station or the server may be designated to be overwritten or both may be reviewed against more complex criteria in order to propagate the required version.

Data content may be secured using content encryption 18 and content decryption 19. The keys to enable such encryption and decryption may be provided by the content key provision at the server.

The system provides a method for exchanging information over a data link with management and control over the content delivery. This provides the user with the facility to download significant volumes of content at times that make optimum use of the communications medium available. The addition of encryption to both the transmission channel and the content itself enable the practical implementation of other valuable features.

Users subscribe to the service in order to gain convenient access to any of the forms of content that can be provided. Thus a user is guided to download the end station client by a content provider who wishes to deliver a large volume of data to the user. When this referral is by means of an existing Internet web site then the appropriate links can be provided to collect all the necessary set-up and configuration data from the user to enable configuration of the end station and connection to the appropriate service provider.

Once installed the end station makes initial contact with the server to perform initial configuration and synchronisation between the end station and the server. It is during this initial contact that the server passes detailed configuration parameters and connection schedules to the end station and enables certain features as required by the user. These features may be subject to an appropriate subscription from the user.

Connection by the end station to the server then continues as determined by the configurations and schedules instructed by the server and updated as necessary. The schedule is controlled from the server but are set with due regard for the user's preferences. These preferences are set manually by the user within the end station client and are therefore signalled on to the server or set directly by accessing a control website. Further information is deduced by the end station by monitoring the usage of the system and is signalled back to the server. In this example information is collected on machine utilisation, usage times and connection times in order to assist in the schedule creation.

The schedule may also contain instructions for the end terminal to connect to alternative providers or services and details of the content to be obtained. Thus alternative servers may be granted permission to provide alternative schedules to the end station from time to time. Therefore it is also possible for the server to schedule a direct connection between two end stations for the purpose of exchanging specific content directly, for instance where such content is considered to be confidential.

When the end station has connected to the server over the Internet the server has the ability to re-allocate the domain and host address and the associated port, in order to redirect the end station to an alternative server for direct exchange of content.

When the end station has connected to the server over an Intranet the system can be used to synchronise content on an incremental and efficient basis.

Content exchange between the end station and server is scheduled by the server to fulfil the preferences and priorities as determined by the user and any content provider. The content exchange takes place subject to the constraints of connection schedules and timings, and content is exchanged on an incremental basis.

Priorities are revised dynamically, with the ability to decline unwanted downloads or re-prioritise partially completed exchanges.

The system provides the facility to designate content for synchronisation and then monitor the content status against a set of criteria. It is therefore possible to cause content to upload to the server, download from the server or to be reviewed and the most up-to-date copy selected. Use of these features allows controlled updating of data and software on a computer terminal as determined by the server. For example, an employer may keep many employees computers updated to the same standard without the intervention of the user, or a supplier may maintain software or information at the latest revision on a transparent basis.

Content exchanges are encrypted during transmission to protect the security of the content over the link between the end station and the server. The content is then decrypted at the receiving end before storage. Key management is controlled by collaboration between the end station and the server.

Content is compressed prior to transmission in order to minimise the amount of data transferred and therefore minimise the connection time necessary. Content is then correspondingly decompressed following receipt.

External content providers may provide data for download. The incremental nature of the data exchange process permits the download of significant volumes of content as this may be continued progressively over several connection sessions.

A further level of encryption allows the content to be encrypted before transmission and decrypted only following authorisation from the content owner. This permits a very high level of efficiency in the download process. Firstly, the user can confirm successful download of the file before paying for the authorisation to unlock the content. Secondly, popular content can be downloaded as a broadcast or streaming activity to numerous users, errors corrected later until successful download can be confirmed and then decrypted for access following confirmation of authorisation.

This further level of encryption also allows the user to exchange data utilising a higher level of security. A further additional level of security can also be added by restricting the forward transmission of such encrypted data to other users connecting directly to same ISP server or directly from end station to end station as scheduled by the server. Thus the system can effectively provide an electronic equivalent of a security courier service between subscribers.

It is common for organisations to introduce security measures in order to control the type of interconnection that can be established over their networks. For example, devices such as firewalls can inspect the content of blocks of data in order to accept or reject each one on an individual basis. It is a feature of the present invention that, as the information being transmitted is already split into batches, it can be wrapped inside an alternative protocol in order to appear to be a different form of data. For example, batches of data can be wrapped within hypertext transfer protocol (HTTP) and coded as though the data itself is hypertext mark-up language (HTML) or extensible mark-up language (XML) in order that a firewall “sees” the data as a standard Internet browser request for a web-page and therefore allow it to pass unhindered. It should be appreciated that these data blocks could be wrapped within a number of alternative protocols to achieve a similar effect in various circumstances.

A user will gain the following benefits from the system:

a. more efficient use of communication resources in that the system can allocate telephone lines to be utilised when not otherwise required, for example overnight;

b. reduced cost by utilising communication resources during off-peak times;

c. transfer of large amounts of data without manual intervention;

d. transfer of large amounts of data without significant impact from communication failures;

e. the ability to reject unwanted data before downloading;

f. improved security of encrypted transmissions;

g. automated incremental backup;

h. automated incremental restoration of backups;

i. automatic loading and configuration of machine software;

j. pre-warning of disc space limitations before downloads;

k. synchronisation of collaborative data i.e. calendars and address books;

l. improved access to chargeable content; and

m. faster access to content where it is downloaded and held locally.

The ISP will gain the following benefits from the system:

a. improved load balancing through better control of connection times;

b. improved capital utilisation through increased throughput over an extended time period;

c. dynamic control over connection times through the ability to split downloads over many sessions;

d. dynamic control over individual means of connection to ensure content is delivered by the most efficient and direct route;

e. increased download size through the ability to split downloads over many sessions;

f. improved facilities for provision of chargeable services through the ability to deliver encrypted material;

g. improved facilities for provision of chargeable services through increased download capacity; and,

h. increased revenue prospects through additional chargeable service provision.

The content provider will gain the following benefits from the system:

a. improved revenue control over downloaded material through content encryption;

b. improved revenue from the ability to download significantly larger content;

c. ability to download new software to control remote machine configuration over a large estate of users;

d. ability to update software revisions over a large estate of users; ability to synchronise multiple sites; and,

e. enlarged user base through improved download facilities.

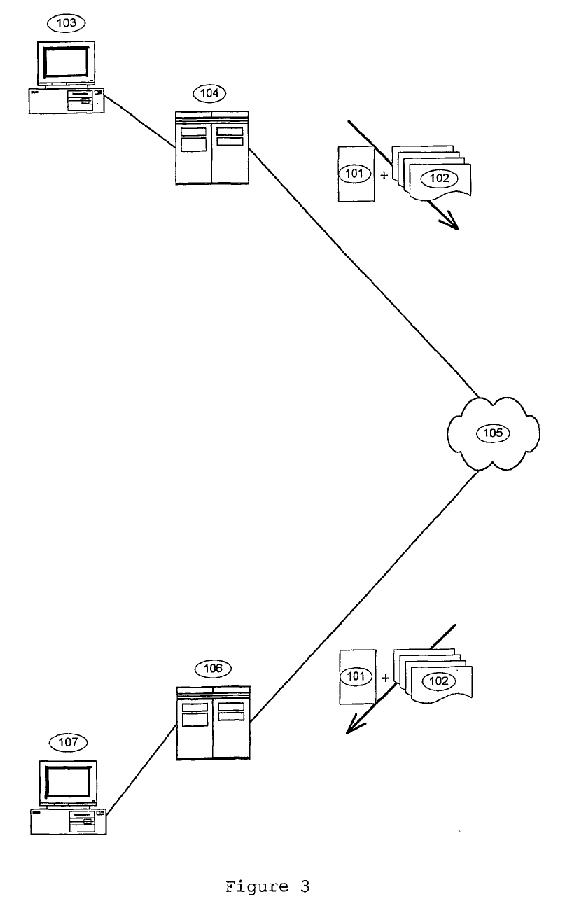

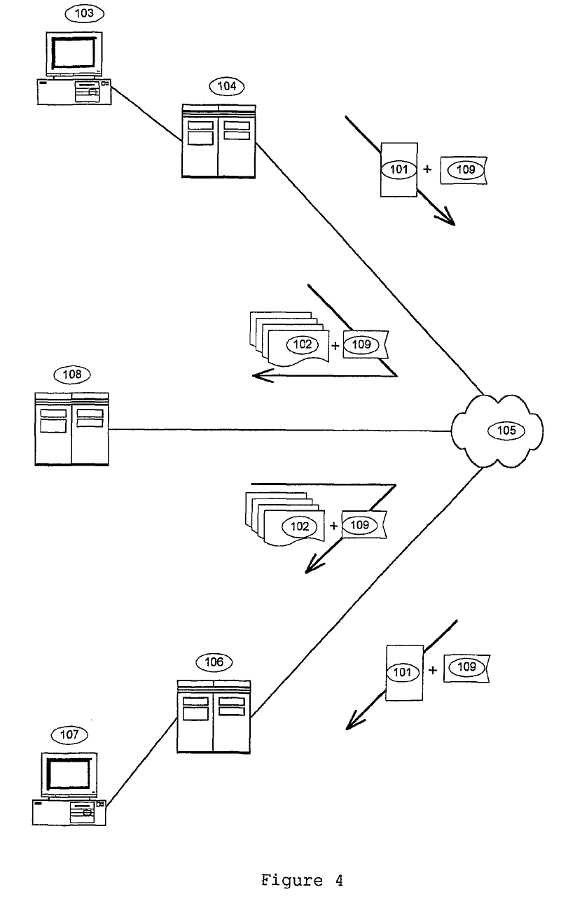

FIGS. 3 and 4 relate to a second aspect of the present invention, which utilises the first aspect of the present invention.

FIG. 3 is a schematic representation of an e-mail and attachment being sent in a conventional manner, from a first end station 103 to a second end station 107. The e-mail 101 and the attachment 102 are sent together via a local Internet server 104 across the Internet 105. The e-mail and the attachment reach the second end station 107 together via a server 106.

FIG. 4 shows an example of an e-mail apparatus in accordance with the present invention.

An attachment client provides the user with the functionality required to send attachments via an alternative route. It operates in conjunction with an existing e-mail client, for example dedicated e-mail client software on an end-station or an e-mail client provided as a web-based utility.

The attachment client described may exist as a single entity or its functionality may be distributed to different parts of the system, or be an integral part of another machine or system that also performs other functions. It may operate in conjunction or be integrated with other apparatus. Examples might be as software loaded onto a computer or as a component within an e-mail capable appliance, such as a telephone instrument or television set.

The attachment client has the facility to be linked in to the existing e-mail client so that it can be activated by the user in order to facilitate sending or receiving of an attachment via the alternative route. The attachment client being utilised is located on the user's own end-station or on an alternative end-station so that the attachments may be originated or received in alternative locations.

In order to send an attachment by the alternative route, the attachment client can be activated by various means, including manually using a button, or automatically by detecting certain parameters, such as the size of the attachment. When the attachment client has been activated it generates a block of data to identify various parameters related to the attachment, which includes information gathered from various sources that may include the originating client, attachment, destination server and receiving client. This data may, for example, include information about size, format, file structures, directory structures, security, compression, encryption, locking, storage location, distribution, timing, priority, importance, and account status and payment.

A token 109 containing the block of data is attached to the e-mail in place of the attachment and despatched in the normal way to the recipient, as described with reference to FIG. 3. The transferof the token 109 to the recipient is straightforward as its size remains small even when the attachment it represents is large.

The attachment client then communicates with the attachment server 108 and makes arrangements to upload the attachment 102 and a copy of the token 109 to a temporary location using separate means agreed between the attachment client and the attachment server 108.

Additionally, further communications are generated to inform the recipient of the status of the upload process. For example, an e-mail message could confirm that the upload process has reached an advanced stage and that the download process may now commence. Thus it is not necessary for the upload to the server to be completed before the download commences.

Both the originator and the recipient communicate with the attachment server 108 to facilitate the setting of various parameters that are used to control the upload and download of attachments 102. It is therefore possible to arrange for the attachments to be originated and received at alternative locations to those normally used. Thus a businessman may arrange to have the download of important presentation material diverted to his hotel to be available when he arrives.

In order to receive an attachment via the alternative route the attachment client must first be activated. This may be achieved by various means, for example it may be activated automatically by the e-mail client when a token attached to an incoming mail message is detected. Alternatively the user may activate it manually after being prompted by viewing the token.

If the attachment client is not already present on the recipients end-station, the token 109 may provide a visual indication or link leading to facilities to install the client on the various e-mail devices.

Once the attachment client has detected the token 109 and read the contents it then communicates with the attachment server 108 and makes arrangements to download the attachment 102 to the temporary location using separate means agreed between the attachment client and the attachment server. Alternatively, this downloading process may be arranged manually by the user from information or links provided directly to the user by the token 109.

When the downloading process has been commenced or completed a message can be automatically returned to the originator as confirmation.

The attachment server 108 provides the alternative service to the originator and the recipient. The server enables the organisation or ISP to provide the alternative attachment service to its users or subscribers.

The attachment server 108 is a server providing the facility for the upload and download of an attachment independently of the e-mail service. The server may provide other related functionality in addition to uploading, storing and downloading the attachments. The attachment server 108 described may exist as a single entity or various functionality may be distributed to different parts of the system or be an integral part of another machine or system that also performs other functions. It may operate in conjunction or be integrated with other apparatus. Examples might be where the attachment server functionality is provided as software to be loaded onto an existing server or loaded onto additional servers coupled in to other data processing systems.

To operate in accordance with the present invention it is necessary for the server 108 and the end-stations 104, 107 to co-operate in the manner of uploading and downloading of the attachments 102 and in the creation of the token 109 which is passed from the originator to the recipient. In addition, the attachment server 108 may perform additional processing on the attachment as defined in the token 109. For example this additional processing could include format translation, language translation, multiple encryption and document locking. This may be particularly useful where the processing is specific to the recipient, for instance where a document may be locked for only a specific user to access. Thus a document may be transmitted in a standard format and may be password protected at the server without the originator knowing the recipient's password. In this way it is possible for material to be downloaded to a third party organisation to be collected by the recipient and for the content to be protected by use of a password known only to the user or alternatively by a series of randomly generated single-use keys previously agreed. These facilities would enable the distribution of data through a series of agency organisations operating in a manner similar to that of courier delivery services. Data can therefore be exchanged with any one of a number of distribution offices positioned in convenient locations such as city centres, airports, hotels and the like.

In order to take advantage of the facility, it is necessary for the originator to set up an account on the server by registering for the service. In so doing, the originator is provided with appropriate client software by the server. For example, the client software includes the attachment client and any upload/download control client required by the system.

When the originator has a requirement to send an attachment by the alternative route, the client software is activated and facilitates the selection of the attachment to be sent. The client software then communicates with the attachment server and thereby declares certain information about the attachment. Thus the server is able to validate the user account details and then issue information to the originator to be incorporated into the token. This information provides a link to the attachment to enable the logical co-ordination of the uploading and downloading process.

The token is then attached to the e-mail in place of the attachment and despatched to the recipient and passed with the attachment to the attachment server.

The invention provides a method for enabling the automated transfer of selected attachments to e-mail messages by an alternative route to that taken by the e-mail message.

Where large files or multiple files are attached to an e-mail message there are numerous problems in transmitting these to the recipient. Such problems are commonplace and the transfer of very large files by this method is not reliable and not much used.

Alternative methods are available, such as uploading and downloading the files to and from web-space at an Internet Service Provider (ISP). These methods solve only some of the problems and generally imply a high level of user knowledge and so are also little used.

The present invention provides a method for enabling and automating the usage of such a specialist utility for e-mail attachments.

When the user wishes to send a large file or multiple files to a remote user we provide means for the attachment to be substituted by a token that provides information to co-ordinate and enable the transfer of the attachment by an alternative route.

When the e-mail is created the user is given the means to select the files to be transmitted. In addition, any options that are permitted for the alternative route could be selected at this stage. For example compression, encryption, file locking, alternative destinations, distributions, delivery priority and the like.

A token is created to represent the attachment in the e-mail. This token will consist of information required at the server and the receiving end-station related to the transmission, processing and recovery of the attachment. This token includes information relating to the temporary location of the attachment and other related information and parameters.

The user will gain the following benefits from the system:

a. large e-mail attachments may be sent or received without the normal limitations imposed by a service provider;

b. attachments may be transferred automatically without the active involvement of the user;

c. attachments may be transferred at times when the network connection is otherwise unused;

d. attachments may be transferred when the computer is otherwise unused;

e. large e-mail attachments may be sent or received without the limitations imposed by line and communications channel shortcomings;

f. larger attachments can be accommodated enabling additional services to be provided;

g. attachments may be delivered to alternative locations ready for collection by the recipient;

h. attachments can be protected by encryption or locked by passwords;

i. payment for the transfer service may be made by either the originator or the recipient;

j. priority delivery service can be provided where requested by either the originator of the recipient; and,

k. attachments can be processed at the attachment server to facilitate conversion to alternative formats or languages.

1. A method of transferring data via a communications network from a first network node to a second network node, comprising the steps of;
dividing the data into batches;
transferring information to the second node from the first node in the batches, and maintaining a record of the transfer status for each batch; and
in the event of a transmission failure or disconnection, reestablishing a connection between the first node and the second node and transferring to the second node from the first node only that batch or those batches of the data not yet successfully received by the second node.

2. A method according to claim 1, wherein the record includes information about the size and location of each batch within the data.

3. A method according to claim 1 or 2, further comprising the step of scheduling the connection and disconnection of the first node or second node to the communications network.

4. A method according to any preceding claim, further comprising the step of reassembling the batches of information at the second node in accordance with the record.

5. A method according to any preceding claim, wherein the communications network comprises the Internet.

6. A method according to any preceding claim, further comprising the step of:
wrapping each batch of data in an alternative protocol in order to appear to be a different form of data.

7. A method according to any preceding claim, further comprising the steps of:
encrypting the information sent to the second node; and
decrypting the information received from the first node as permitted and required at the second node.

8. A method according to any preceding claim, wherein the first and second nodes comprise a network server and an end station.

9. A method according to any preceding claim, wherein the scheduling of the connection and disconnection of the end station to the communications network is dependent upon various parameters derived locally, including information down loaded from the server to the end station.

10. A method according to any preceding claim, wherein the data includes at least one of e-mails, attachments to e-mails and web pages.

11. An apparatus for transferring data via a communications network from a first network node to a second network node, comprising:
means to divide the data into batches;
means to transfer information to the second node from the first node in the batches, and maintain a record of each batch; and
means to reestablish a connection between the first node and the second node in the event of a transmission failure or disconnection and means to transfer to the second node from the first node only that batch or those batches not yet successfully received by the second node.

12. An apparatus according to claim 11, further comprising means to schedule the connection and disconnection of the first node or second node to the communications network.

13. An apparatus according to claim 11 or 12, further comprising means to reassemble the batches of information at the second node in accordance with the record.

14. An apparatus according to any one of claims 11 to 13, wherein the communications network comprises the Internet.

15. An apparatus according to any one of claims 11 to 14, further comprising:
means to wrap each batch of data in an alternative protocol.

16. An apparatus according to any one of claims 11 to 15, further comprising:
means to encrypt the information sent to the second node; and
means to decrypt the information received from the first node as permitted and required at the second node.

17. An apparatus according to any one of claims 11 to 16, wherein the first and second nodes comprise a network server and an end station.

18. An apparatus according to any one of claims 12 to 17, wherein the scheduling of the connection and disconnection of the end station to the communications network is dependent upon various parameters derived locally, including information down loaded from the server to the end station.

19. An apparatus according to any one of claims 11 to 18, wherein the data includes at least one of e-mails, attachments to e-mails and web pages.

20. A method of transferring an email and an attachment from a first end station to a second end station, comprising the steps of:
generating a token containing information about the attachment;
sending the email and a copy of the token to the second end station;
sending the attachment and a copy of the token to an attachment server in accordance with the method of any one of claims 1 to 10; and
sending the attachment and a copy of the token to the second end station from the attachment server in accordance with the method of any one of claims 1 to 10.

21. A method according to claim 20, wherein the token contains information gathered from one or more of the first end station, the second end station, an intermediate server and the attachment.

22. A method according to claim 20 or 21, wherein the attachment server generates reports relating to the status of the uploading or downloading of the attachment to or from the attachment server.

23. A method according to any one of claims 20 to 22, wherein the attachment is only routed via the attachment server when the attachment is greater than a predetermined size.

24. An apparatus for transferring an email and an attachment from a first end station to a second end station, comprising:
means for generating a token containing information about the attachment;
means for sending the email and a copy of the token to the second end station;
means for sending the attachment and a copy of the token to an attachment server in accordance with the apparatus of any one of claims 11 to 19; and
means for sending the attachment and a copy of the token to the second end station from the attachment server in accordance with the apparatus of any one of claims 11 to 19.

25. An apparatus according to claim 24, wherein the token contains information gathered from one or more of the first end station, the second end station, an intermediate server and the attachment.

26. An apparatus according to claim 24 or 25, wherein the attachment server includes means to generate reports relating to the status of the uploading or downloading of the attachment to or from the attachment server.
